(19) United States
(12) Patent Application Publication
(10) Pub. No.: US 2006/0170088 A1
(43) Pub. Date: Aug. 3, 2006

(54) Spacer Structures for Semiconductor Package Devices

(75) Inventors: Hsin-Hui Lee, Kaohsiung (TW); Mirng-Ji Lii, Hsin-Chu (TW); Chien-Hsiun Lee, Hsin-Chu (TW); Hsin-Yu Pan, Taipei (TW); Tsorng-Dih Yuan, Hopewell Junction, NY (US)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: TAIWAN SEMICONDUCTOR MANUFACTURING COMPANY, LTD., Hsinchu (TW)

(21) Appl. No.: 10/906,055

(22) Filed: Feb. 1, 2005

(51) Int. Cl. H03H 9/00; H01L 23/02

(52) U.S. Cl. 257/686

(57) ABSTRACT

Disclosed are novel spacer structures for stacked semiconductor package devices. In addition, methods of manufacturing spacers and stacked semiconductor package devices having such spacers are also disclosed. In one embodiment, a spacer includes a first mounting surface couplable to a longitudinal face of a first substrate, where the first mounting surface has a first surface area. The spacer also includes a second mounting surface substantially parallel to the first mounting surface and located on an opposing side of the spacer from the first mounting surface. Furthermore, the second mounting surface is couplable to a longitudinal face of a second substrate and has a second surface area larger than the first surface area.

### FIELD OF THE INVENTION

This disclosure relates generally to manufacturing techniques for semiconductor devices, and more particularly to novel spacer structures for stacked semiconductor package devices.

### BACKGROUND

The packaging of integrated circuit (IC) chips is one of the most important steps in the manufacturing process, contributing significantly to the overall cost, performance and reliability of the packaged chip. As semiconductor devices reach higher levels of integration, packaging technologies, such as wirebonding, have become critical. Packaging of the IC chip accounts for a considerable portion of the cost of producing the device and failure of the package leads to costly yield reduction.

As semiconductor device sizes have decreased, the density of devices on a chip has increased, along with the size of the chip, thereby making the wirebonding of chips to other components more challenging. One of the problems that may lead to device failure is the integrity of the wirebond connections formed on the chip substrates. As chip sizes increase, the density of wirebond connections is also increased, which may result in a higher number of wirebond failures. In addition, since chip real estate is limited, the area for wirebonding the chip to other circuitry can only hold a given number of connections. Problems can also occur with the encapsulation of a finished stacked device, for example, having the encapsulating material flow evenly and adequately between the stacked substrates in the package device, as well as the spacers used to separate those substrates. Without proper flowing of the encapsulant, device operation and longevity may also suffer.

### SUMMARY

Disclosed are novel spacer structures for stacked semiconductor package devices. In addition, methods of manufacturing spacers and stacked semiconductor package devices having such spacers are also disclosed. In one embodiment, a spacer includes a first mounting surface couplable to a longitudinal face of a first substrate, where the first mounting surface has a first surface area. The spacer also includes a second mounting surface substantially parallel to the first mounting surface and located on an opposing side of the spacer from the first mounting surface. Furthermore, the second mounting surface is couplable to a longitudinal face of a second substrate and has a second surface area larger than the first surface area.

In such embodiments, the smaller surface area of the first (e.g., lower) mounting surface of such a spacer, which is mounted to one side of an active substrate, permits wirebond connections to be made on a larger portion of the upper surface of that substrate, since less of the substrate's upper surface is covered by the spacer. In addition, such package device spacers may also allow for increased thermal transfer among interlevel substrates by covering up less surface area of the substrates, and thus allowing heat to escape directly from a substrate to the surrounding ambient, which is typically a dielectric encapsulant material. Still further, the larger upper mounting surface of the spacer provides beneficial overhang support for a mounted substrate, particularly in embodiments where the upper mounting surface has a surface area that is substantially equal with a surface area of the substrate.

In another embodiment, a spacer includes a first mounting surface couplable to a longitudinal face of a first substrate, and a second mounting surface substantially parallel to the first mounting surface and located on an opposing side of the spacer from the first mounting surface. In such embodiments, the second mounting surface is couplable to a longitudinal face of a second substrate. Also in this embodiment of the spacer, a footprint of the first or second mounting surface is formed as substantially non-rectilinear. In such embodiments, by providing substrate spacers having non-rectilinear footprints on their mounting surfaces in stacked semiconductor package devices, the encapsulating process used to seal such devices is improved. For example, pockets in the encapsulant material are less likely to form near or around the sharp corners found in conventional rectilinear-shaped spacer footprints. Thus, gases may be avoided that could form in such pockets, as well as other results that may threaten device operation or longevity.

### BRIEF DESCRIPTION OF THE DRAWINGS

FIG. 1 illustrates one embodiment of a semiconductor package substrate spacer constructed according to the disclosed principles;

FIG. 2 illustrates a stacked semiconductor package device incorporating spacers constructed in accordance with the disclosed principles;

FIG. 3 illustrates the stacked semiconductor package device shown in FIG. 2 constructed next to a second stacked semiconductor device;

FIG. 4 illustrates one embodiment of another advantageous spacer that maybe employed in stacked semiconductor devices; and

FIG. 5 illustrates a top view of another environment of a spacer constructed as disclosed herein.

### DETAILED DESCRIPTION OF THE EMBODIMENTS

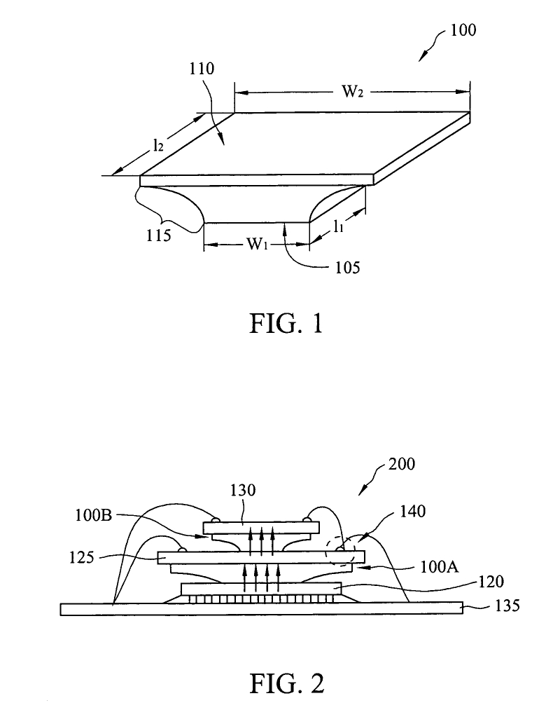

FIG. 1 illustrates one embodiment of a semiconductor package substrate spacer 100 constructed according to the disclosed principles. As illustrated, the spacer 100 includes a first mounting surface 105 on what would be its bottom surface, as well as a second mounting surface 110 on what would be its upper surface, when mounted in a stacked semiconductor package device, such as a multi-chip module (MCM).

As shown in FIG. 1, the first mounting surface 105 is substantially parallel to the second mounting surface 110, the two mounting surfaces 105, 110 are located on opposing sides of the spacer 100. In addition, the first mounting surface 105 has a first surface area, defined by a longitudinal width w₁ and length l₁, and the second mounting surface 110 has a second surface area, defined by a longitudinal width w₂ and length l₂. In accordance with the disclosed principles, the second surface area (i.e., the surface area of the second mounting surface 110) is larger than the first surface area. As is also shown in FIG. 1, the sides 115 of the spacer 100 comprise a transition from the first mounting surface 105 to the second mounting surface 110 that is a concave curved or arced transition 115. Such a transition 115 may be created using an isotropic wet etch process when forming the spacer. Another embodiment for transition 115 may simply be linear from the edges of the first mounting surface 105 to the edges of the second mounting surface 110.

FIG. 2 illustrates a stacked semiconductor package device 200, such as an MCM, incorporating spacers constructed in accordance with the disclosed principles. In this embodiment, the stacked device 200 includes two spacers, 100A, 100B, both constructed in accordance with the embodiment disclosed in FIG. 1. As illustrated, the first spacer 100A is coupled between a first substrate 120 and the second substrate 125. Specifically, a first mounting surface of the first spacer 100A is coupled to the upper surface of a lower substrate 120, while a second mounting surface of the first spacer 100A is couple to the bottom surface of a second substrate 125. Similarly, the second spacer 100B is coupled between the second substrate 125 and the third substrate 130, and more accurately, a first mounting surface of the second spacer 100B is coupled to the upper surface of the second substrate 125, while a second mounting surface of the second substrate 100B is couple to a lower surface of the third substrate 130.

As discussed with respect to FIG. 1, the first and second spacers 100A, 100B both include the first and second mounting surfaces located on opposing sides of their respective spacer 100A, 100B. Also as discussed with reference to FIG. 1, the first mounting surfaces of the first and second spacers 100A, 100B have respective first surface areas that are substantially less than the corresponding second surface areas of the second mounting surfaces of those first and second spacers 100A, 100B. As such, each of the first and second spacers 100A, 100B have curved transitions when moving from their respective first mounting surfaces and second mounting surfaces. By having second mounting surfaces with surface areas substantially larger than that of their respective first mounting surfaces, each of the spacers 100A, 100B are capable of supporting large substrates (e.g., 125, 130, respectively) on their second mounting surfaces relative to the smaller surface areas of their first mounting surfaces. In some embodiments, the surface areas of the supported substrates 125, 130 are substantially co-extensive with the surface areas of the respective upper (e.g., second) mounting surfaces of the first and second spacers 100A, 100B, yet in such embodiments only about one-half of the substrate upper surface area (e.g., having active areas/bonding pads) is occupied by the corresponding lower (e.g., first) mounting surfaces of the spacers 100A, 100B.

Once the stacked semiconductor device 200 has been constructed using spacers 100A, 100B as disclosed herein, the stacked device 200 may then be mounted on another structure, such as a printed circuit board (PCB) 135. As shown, mounting the stacked device 200 to the PCB 135 may be accomplished using conventional flip-chip techniques, if desired. By constructing the stacked semiconductor device 200 using spacers 100A, 100B constructed according to the disclosed principles, the resulting device 200 contains significant advantages over conventional stacked semiconductor package devices.

As is shown in FIG. 2, the smaller surface areas of the first mounting surfaces of the spacers 100A, 100B permits wirebond connections to be made on a larger portion of the upper surfaces of the semiconductor substrates 125, 130. As result, a larger number of wirebond connections maybe made on the open surface area of each single substrate 125, 130 than may be accomplished when conventional spacers are employed in such stacked devices. Moreover, since a larger surface area of the substrates 125, 130 are available for receiving wirebond connections, those wirebond connections may also be made larger than typically possible when conventional spacers are employed, therefore increasing the strength of the wirebonds within the package device 200.

Additionally, spacers constructed in accordance with the disclosed principles also offer improved heat-spreading capabilities within stacked semiconductor package devices. More specifically, as the semiconductor substrate, which are typically integrated circuits chips, are operated within the completed package device, the substrates themselves begin to generate more and more heat. Even in conventional devices, the spacers between such substrates are typically constructed from dielectric materials, such as silicon, that are capable of transferring heat away from the interlevel substrates (e.g., 120, 125, 130). However, package device spacers constructed as disclosed herein allow for increased thermal transfer among the interlevel substrates 120, 125, 130 by covering less surface area of the substrates 120, 125 with the first mounting surfaces of the spacers 100A, 100B. As a result, not only may heat be transferred from lower substrates (e.g., 120) up through the spacers 100A, 100B and out to the top of the device 200, but use of spacers constructed as disclosed herein also allows larger upper surface areas of the interlevel substrates 120, 125, 130 to remain uncovered by a spacer and therefore more readily capable of transferring heat into the surrounding ambient.

Still further, all of these benefits are provided by a disclosed package spacer, in addition to the overhang support offered for an interlevel substrate by providing a mounting surface that is substantially equal in surface area with the supported substrate. Such overhang support is provided by constructing the spacer with tapered transitional sides from its bottom surface to its top surface, as discussed above. In the embodiments illustrated in FIGS. 1-3, the novel spacers have been manufactured with a concave curvature when moving from the first to the second mounting surfaces, however, these are included as examples only. As such, the sides of the spacer may be linear when moving from the first (bottom) surface to the second (top) surface, or may include a convex curvature or the illustrated concave curvature.

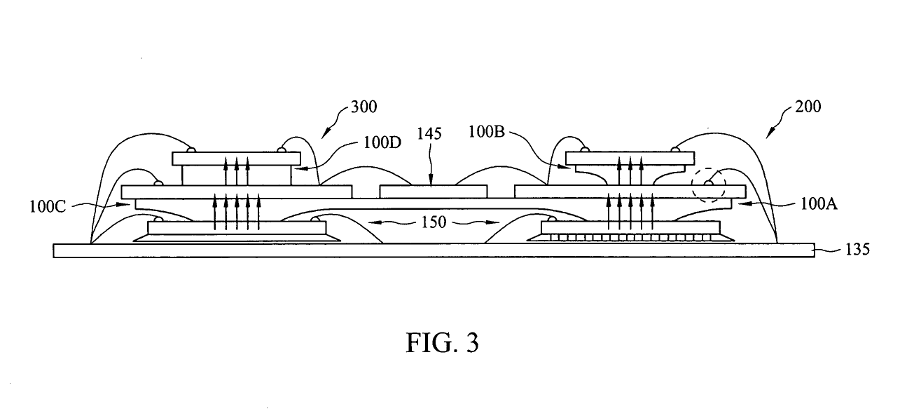

FIG. 3 illustrates the stacked semiconductor package device 200 shown in FIG. 2 constructed next to a second stacked semiconductor device 300. The first stacked device 200 again includes first and second spacers 100A, 100B constructed as discussed above. Similarly, the second stacked device 300 also includes first and second spacers 100C, 100D; however, only its lower spacer 100C has been constructed in accordance with the disclosed principles. As such, its upper spacer 100D is a conventional spacer. As is also shown, the first and second package devices 200, 300 are mounted on another component, such as the PCB 135 discussed above.

In this illustrated embodiment, the lower spacers 100A, 100C of the package devices 200, 300 have been constructed such that they laterally extend towards each other and thus connect the first and second package devices 200, 300. By adjoining the edges of the first spacers 100A, 100C of the package devices 200, 300, another substrate 145, such as another IC chip, may also be coupled to the second (upper) surfaces of these lower spacers 100A, 100C. Moreover, since the overall surface area of the footprints of the first mounting surfaces of the spacer 100A, 100C are substantially smaller than that of the second mounting surfaces of the lower spacers 100A, 100C, active areas of the bottom interlevel substrates are still available to receive wirebond connections (e.g., as illustrated by wirebond connections 150). In short, the embodiment illustrated in FIG. 3 demonstrates that stacked semiconductor devices constructed having spacers as disclosed herein are able to employ a greater number of interlevel substrates than similar package device layouts found in the prior art, while maintaining or even increasing the wirebond capabilities of each such device.

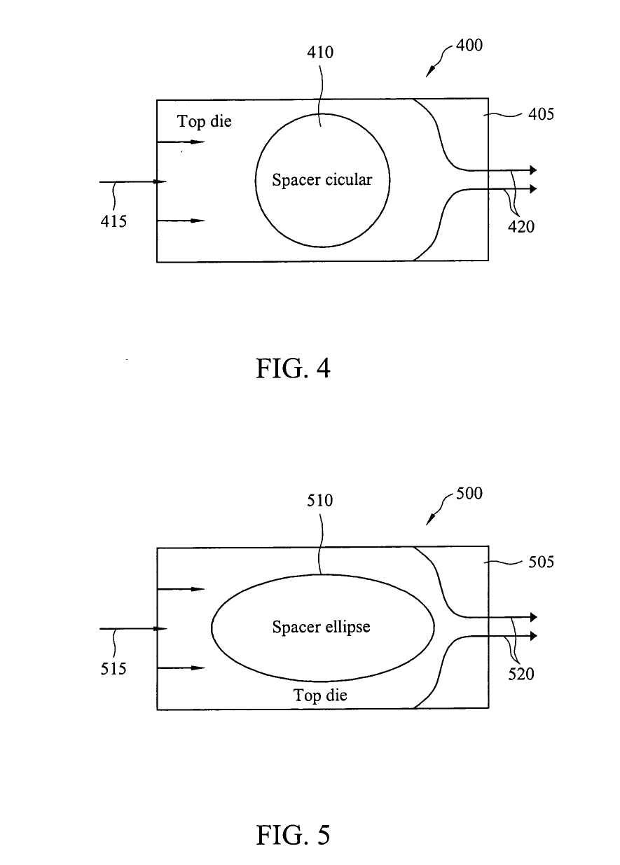

FIG. 4 illustrates one embodiment of another advantageous spacer that maybe employed in stacked semiconductor devices. Most specifically, FIG. 4 shows a top view of a novel spacer 410 as seen through a top substrate (or ‘die’) 145. Once the interlevel substrates of stacked semiconductor devices have been mounted with spacers between them, an encapsulant material is typically flowed over the substrates and around the dielectric spacers.

However, since conventional spacers typically have rectilinear footprints when viewed from above, pockets may form in the encapsulant as it flows around the rectilinear corners of a conventional spacer. In contrast, the novel spacer 410 illustrated in FIG. 4 may be constructed with a non-rectilinear footprint so that the encapsulant material flows more smoothly around the spacer 410, as shown by arrows 415 and 420. In this particular embodiment, the spacer 410 has a substantially circular footprint, however, a spacer constructed as disclosed herein is not limited to any particular non-rectilinear shape.

For example, looking briefly at FIG. 5, a top view of another environment of a spacer 510 constructed as disclosed herein is shown. As with structure 400 in FIG. 4, the structure 500 in FIG. 5 also illustrates a top substrate or die 505 formed over a novel spacer 510. Also as in the previous embodiment, as an encapsulant material is flowed across the device 500 (as shown with arrows 515 and 520) the non-rectilinear shape of the spacer 510 allows for a smooth flow of the encapsulant material around it. In this particular embodiment, the spacer 510 has a substantially elliptical footprint to more easily allow the encapsulant material to flow around it, but again no particular non-rectilinear footprint is intended.

By providing substrate spacers in stacked semiconductor package devices having non-rectilinear footprints, the encapsulating process used to seal such devices is improved. For example, pockets in the encapsulant material are less likely to form near or around the sharp corners found in conventional rectilinear-shaped spacer footprints. Moreover, in some embodiments, by eliminating the rectilinear footprint of the spacer an increase in exposed substrate surface area is provided, which may then provide increased surface area for wirebonding connections as discussed in detail above. As with all the spacers described herein, spacers 410, 510 in FIGS. 4 and 5 may be constructed from a dielectric material, such as silicon; however, no limitation to any particular material is intended. Furthermore, the spacer footprints illustrated in FIGS. 4 and 5 may only constitute one of the external mounting surfaces of the spacer 410, 510, and that spacer's opposing mounting surface (not illustrated) may have a footprint of corresponding shape but larger or smaller in surface area than the illustrated footprint, or even equal in surface area, depending on the application. As a result, not only may spacers constructed as disclosed herein have a tapered cross-section between upper and lower mounting surfaces, as discussed with respect to the FIGS. 1, 2 and 3, but may also include non-rectilinear footprints on either of those mounting surfaces (e.g., upper or lower surfaces), as discussed with respect to FIGS. 4 and 5.

Although the above description sets forth advantages relative to certain prior art implementations, these examples and their performance specifications should not be construed in any way as limitations on the invention or inventions disclosed. The scope of coverage for any patent that issues shall be defined by the claims that any such patent contains. It will be appreciated by those of ordinary skill in the art that the invention can be embodied in other specific forms without departing from the spirit or essential character thereof. The presently disclosed embodiments are therefore considered in all respects to be illustrative and not restrictive. The scope of the invention is indicated by the appended claims rather than the foregoing description, and all changes that come within the meaning and ranges of equivalents thereof are intended to be embraced therein.

Additionally, the section headings herein are provided for consistency with the suggestions under 37 C.F.R. §1.77 or otherwise to provide organizational cues. These headings shall not limit or characterize the invention(s) set out in any claims that may issue from this disclosure. Specifically and by way of example, although the headings refer to a “Technical Field,” the claims should not be limited by the language chosen under this heading to describe the so-called technical field. Further, a description of a technology in the “Background” is not to be construed as an admission that technology is prior art to any invention(s) in this disclosure. Neither is the “Summary of the Invention” to be considered as a characterization of the invention(s) set forth in the claims found herein. Furthermore, any reference in this disclosure to “invention” in the singular should not be used to argue that there is only a single point of novelty claimed in this disclosure. Multiple inventions may be set forth according to the limitations of the multiple claims associated with this disclosure, and the claims accordingly define the invention(s), and their equivalents, that are protected thereby. In all instances, the scope of the claims shall be considered on their own merits in light of the specification, but should not be constrained by the headings set forth herein.

1. A stacked semiconductor device, comprising:
a first substrate having a longitudinal face;
a spacer, comprising:
a first mounting surface coupled to the longitudinal face of the first substrate, the first mounting surface having a first surface area, and
a second mounting surface substantially parallel to the first mounting surface and located on an opposing side of the spacer from the first mounting surface, the second mounting surface having a second surface area larger than the first surface area,
wherein a transition from the first mounting surface to the second mounting surface along the sides of the spacer is curved, and wherein a footprint of the first or second mounting surface is substantially non-rectilinear; and
a second substrate having a longitudinal face coupled to the second mounting surface of the spacer.

2. (canceled)

3. A device according to claim 1, wherein the second surface area is substantially equal to a surface area of the longitudinal face of the second substrate

4. A device according to claim 1, wherein the spacer comprises silicon.

5. A device according to claim 1, wherein an edge of the second mounting surface joins a second mounting surface of a second spacer, the second spacer having a first mounting surface couplable to a longitudinal face of a third substrate and its second mounting surface couplable to a longitudinal face of a fourth substrate.

6. A device according to claim 5, wherein the adjoined second mounting surfaces of the first and second spacers is couplable to a longitudinal face of a fifth substrate positioned between the second and fourth substrates.

7. (canceled)

8. A spacer according to claim 1, wherein the first mounting surface has a surface area substantially equal to a surface area of the second mounting surface.

9. A spacer according to claim 1, wherein the footprint of the first or second mounting surface is substantially elliptical.

10. A spacer according to claim 1, wherein the footprint of the first or second mounting surface is substantially circular.

11. A method of manufacturing a stacked semiconductor device, the method comprising:
forming a spacer having first and second mounting surfaces substantially parallel to each other and located on opposing sides of the spacer, wherein a footprint of the first or second mounting surface is substantially non-rectilinear;
coupling the first mounting surface to a longitudinal face of a first substrate; and
coupling the second mounting surface to a longitudinal face of a second substrate.

12. A method according to claim 11, wherein a surface area of the first mounting surface is substantially equal to a surface area of the second mounting surface.

13. A method according to claim 11, wherein the footprint of the first or second mounting surface is substantially elliptical.

14. A method according to claim 11, wherein the footprint of the first or second mounting surface is substantially circular.

15. A spacer according to claim 8, wherein the footprints of the first and second mounting surface are substantially elliptical.

16. A spacer according to claim 8, wherein the footprints of the first and second mounting surface are substantially circular.
